(19) United States
(12) Patent Application Publication
(10) Pub. No.: US 2019/0154344 A1
(43) Pub. Date: May 23, 2019

(54) RADIATOR

(71) Applicants: Inventec (Pudong) Technology Corporation, Shanghai (CN); INVENTEC CORPORATION, Taipei City (TW)

(72) Inventors: Kai-Yang TUNG, TAIPEI CITY (TW); Hung-Ju CHEN, TAIPEI CITY (TW)

(21) Appl. No.: 15/862,651

(22) Filed: Jan. 5, 2018

(30) Foreign Application Priority Data
Nov. 17, 2017 (CN) 201711141687.0

(51) Int. Cl. F28D 1/053; F28F 1/02; F28F 1/04

(52) U.S. Cl. CPC F28D 1/05383; F28D 1/05333; H05K 7/203; F28F 1/04; F28F 1/022

(57) ABSTRACT

A radiator includes a plurality of first pipe bodies. The first pipe bodies are mutually connected to form a first annular structure. The first pipe bodies are configured to allow a cooling fluid to flow through. Each of the first pipe bodies has a width and a height perpendicular to each other. The height is longer than the width.

### RELATED APPLICATIONS

This application claims priority to Chinese Application Serial Number 201711141687.0, filed Nov. 17, 2017, which is herein incorporated by reference.

### BACKGROUND

### Technical Field

The present disclosure relates to radiators. More particularly, the present disclose relates to radiators used in two-phase immersion cooling systems.

### Description of Related Art

In order to effectively decrease the excessive heat generated during the operation of the large equipment or electronic devices, which may affect the working efficiency or even cause damage, how to effectively achieve a cooling effect is undoubtedly an important issue.

In the application of immersion cooling systems, users immerse the equipment which generates heat during operation into a cooling tank. In general, the cooling tank is disposed with a radiator therein, so as to take away the high temperature in the cooling tank.

### SUMMARY

A technical aspect of the present disclosure is to provide a radiator, which can strength the effect of heat exchange with heated fluid.

According to an embodiment of the present disclosure, a radiator includes a plurality of first pipe bodies. The first pipe bodies are mutually connected to form a first annular structure. The first pipe bodies are configured to allow a cooling fluid to flow through. Each of the first pipe bodies has a width and a height perpendicular to each other. The height is longer than the width.

In one or more embodiments of the present disclosure, each of the first pipe bodies includes a plurality of first subsidiary pipe bodies arranged mutually side by side.

In one or more embodiments of the present disclosure, the first annular structure is a rectangular structure.

In one or more embodiments of the present disclosure, the radiator further includes a plurality of first connecting portions. The first connecting portions are connected between the first pipe bodies. Each of the first connecting portions is mutually communicated with the first pipe bodies mutually connected.

In one or more embodiments of the present disclosure, the radiator further includes a plurality of second pipe bodies and a plurality of second connecting portions. The second pipe bodies are mutually connected to form a second annular structure. The second pipe bodies are configured to allow the cooling fluid to flow through. The second connecting portions are connected between the second pipe bodies. Each of the second connecting portions is mutually communicated with the second pipe bodies mutually connected. The first connecting portions overlap on the second connecting portions. At least one of the second connecting portions is mutually communicated with a corresponding one of the first connecting portions.

In one or more embodiments of the present disclosure, the radiator further includes an inlet structure and an outlet structure. The inlet structure is located at one of the first connecting portions. The outlet structure is located at the corresponding one of the second connecting portions overlapped by the corresponding one of the first connecting portions at which the inlet structure is located.

In one or more embodiments of the present disclosure, the corresponding one of the first connecting portions and the corresponding one of the second connecting portions mutually communicated respectively have a first isolating plate and a second isolating plate therein. The first isolating plate isolates a first internal chamber of the corresponding one of the first connecting portions into a first chamber and a second chamber. The second isolating plate isolates a second internal chamber of the corresponding one of the second connecting portions into a third chamber and a fourth chamber. The second chamber and the third chamber are mutually communicated.

In one or more embodiments of the present disclosure, the radiator further includes an inlet structure and an outlet structure. The inlet structure is located at one of the first connecting portions. The outlet structure is located at one of the first connecting portions.

In one or more embodiments of the present disclosure, the inlet structure and the outlet structure are located at different two of the first connecting portions.

In one or more embodiments of the present disclosure, the inlet structure and the outlet structure are both located at one of the first connecting portions.

When compared with the prior art, the above-mentioned embodiments of the present disclosure have at least the following advantages:

(1) Since the first pipe bodies are mutually connected to form the first annular structure, the heated fluid in the cooling tank can be in contact with the first pipe bodies forming the first annular structure. In other words, the radiator can be disposed completely around an inner space inside the cooling tank to carry out heat exchange, such that the effect of the heat exchange between the heated fluid and the first pipe bodies can be strengthened.

(2) Since the width of each of the first pipe bodies is shorter than the height, the first pipe bodies forming the first annular structure can effectively increase the space utilization rate inside the cooling tank.

(3) Through the formation of the first annular structure, the degree of complexity of the pipelines of the radiator can be effectively reduced, further increasing the space utilization rate inside the cooling tank. Moreover, the radiator can be installed at the inner wall of the cooling tank in a simple and an easy manner, which is convenient to the users.

### BRIEF DESCRIPTION OF THE DRAWINGS

The disclosure can be more fully understood by reading the following detailed description of the embodiments, with reference made to the accompanying drawings as follows:

FIG. 1 is a schematic view of a radiator according to an embodiment of the present disclosure;

FIG. 2 is a schematic view of a radiator according to another embodiment of the present disclosure;

FIG. 3 is a schematic view of a radiator according to a further embodiment of the present disclosure; and

FIG. 4 is a partial perspective view of the first connecting portion and the second connecting portion of FIG. 3.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

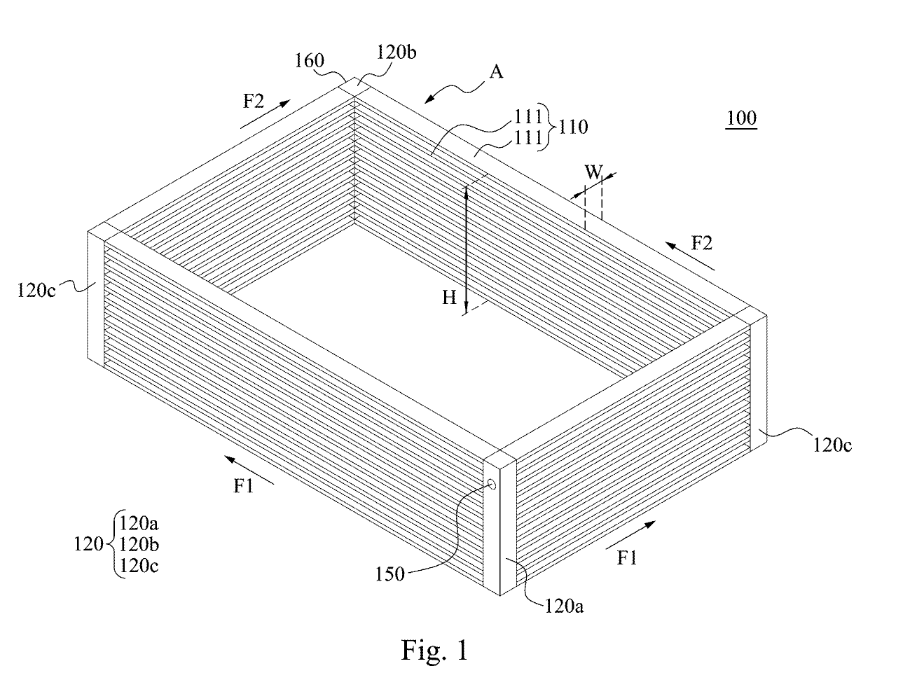

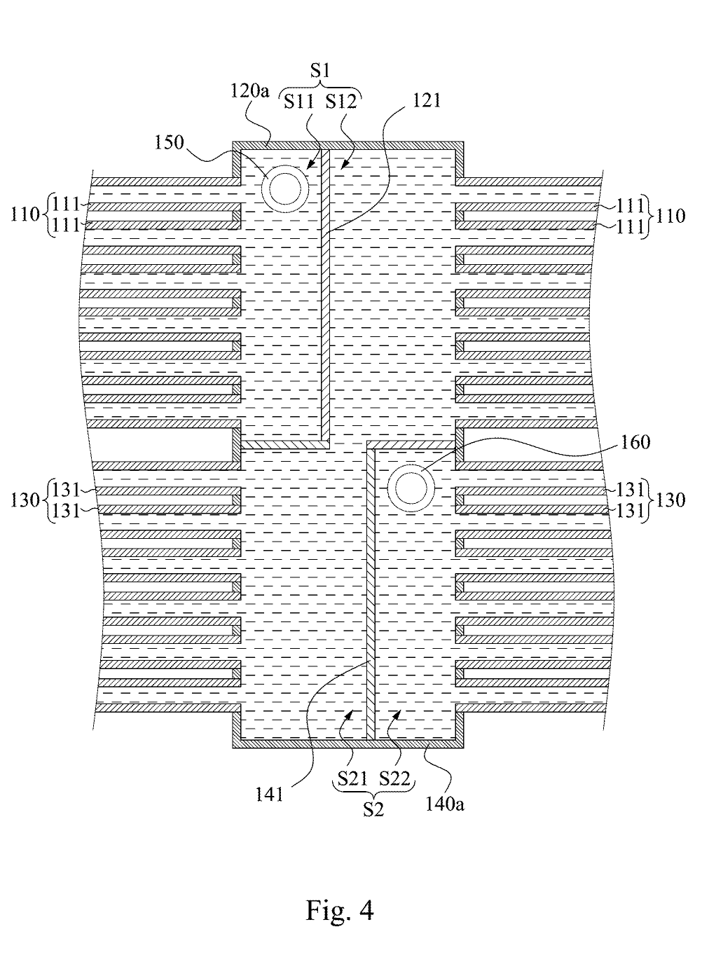

Reference is made to FIG. 1. FIG. 1 is a schematic view of a radiator 100 according to an embodiment of the present disclosure. In this embodiment, as shown in FIG. 1, a radiator 100 is suitable to be used in a two-phase immersion cooling system (not shown). The radiator 100 includes a plurality of first pipe bodies 110. The first pipe bodies 110 are mutually connected to form a first annular structure A. The first pipe bodies 110 are configured to allow a cooling fluid C (please see FIG. 4) to flow through. Each of the first pipe bodies 110 has a width W and a height H perpendicular to each other. To be specific, the height H is longer than the width W.

When the radiator 100 is perpendicularly disposed inside a cooling tank (not shown), an outside of the first annular structure A can be installed at an inner wall of the cooling tank. As mentioned above, the height H is longer than the width W, which means the width W of each of the first pipe bodies 110 is shorter than the height H. In this way, the first pipe bodies 110 forming the first annular structure A can effectively increase the space utilization rate inside the cooling tank.

In addition, through the formation of the first annular structure A, the degree of complexity of the pipelines of the radiator 100 can be effectively reduced. Therefore, the space utilization rate inside the cooling tank is further increased. Moreover, the radiator 100 can be installed at the inner wall of the cooling tank in a simple and an easy manner, which brings convenience to the users.

Furthermore, since the first pipe bodies 110 are mutually connected to form the first annular structure A, the heated fluid in the cooling tank can be in contact with the first pipe bodies 110 forming the first annular structure A. In other words, the radiator 100 can be disposed completely around an inner space inside the cooling tank to carry out heat exchange, such that the effect of the heat exchange between the heated fluid and the first pipe bodies 110 can be strengthened. For example, the heated fluid can be dielectric liquid vapor.

It is worthy to note that the outside of the first annular structure A can be correspondingly adjusted in shape with regard to the shape of the inner space of the cooling tank. For example, in this embodiment, the first annular structure A is a rectangular structure. However, this does not intend to limit the present disclosure.

In order to further strengthen the effect of heat exchange between the heated fluid and the first pipe bodies 110, in this embodiment, each of the first pipe bodies 110 includes a plurality of first subsidiary pipe bodies 111. To be more specific, the first subsidiary pipe bodies 111 are arranged mutually side by side.

In the structural point of view, as shown in FIG. 1, the radiator 100 further includes a plurality of first connecting portions 120 (including the first connecting portions 120a, 120b, 120c). The first connecting portions 120 are connected between the first pipe bodies 110. Each of the first connecting portions 120 is mutually communicated with the first pipe bodies 110 mutually connected. In other words, the cooling fluid C can also flow through the first connecting portions 120. Moreover, the radiator 100 further includes an inlet structure 150 and an outlet structure 160. The inlet structure 150 is located at one of the first connecting portions 120. The outlet structure 160 is also located at one of the first connecting portions 120. The inlet structure 150 allows the cooling fluid C to flow to the corresponding connecting portion 120 and thus to flow inside the first subsidiary pipe bodies 111. The outlet structure 160 allows the cooling fluid C to flow away from the corresponding connecting portion 120.

According to the actual situation, the inlet structure 150 and the outlet structure 160 can be located at different two of the first connecting portions 120. For example, in this embodiment, as shown in FIG. 1, the inlet structure 150 and the outlet structure 160 are respectively located at the first connecting portions 120a, 120b opposite to each other (the outlet structure 160 in FIG. 1 is located at the back of the first connecting portion 120b, and is thus blocked by the first connecting portion 120b). In this way, after the cooling fluid C flows to the first connecting portion 120a through the inlet structure 150, the cooling fluid C then flows along the first subsidiary pipe bodies 111 along the flowing directions F1 at the two sides to the first connecting portions 120c, and then turns to flow along the flowing directions F2 to the first connecting portion 120b. Moreover, according to the actual situation, the inlet structure 150 and the outlet structure 160 can also be both located at one of the first connecting portions 120.

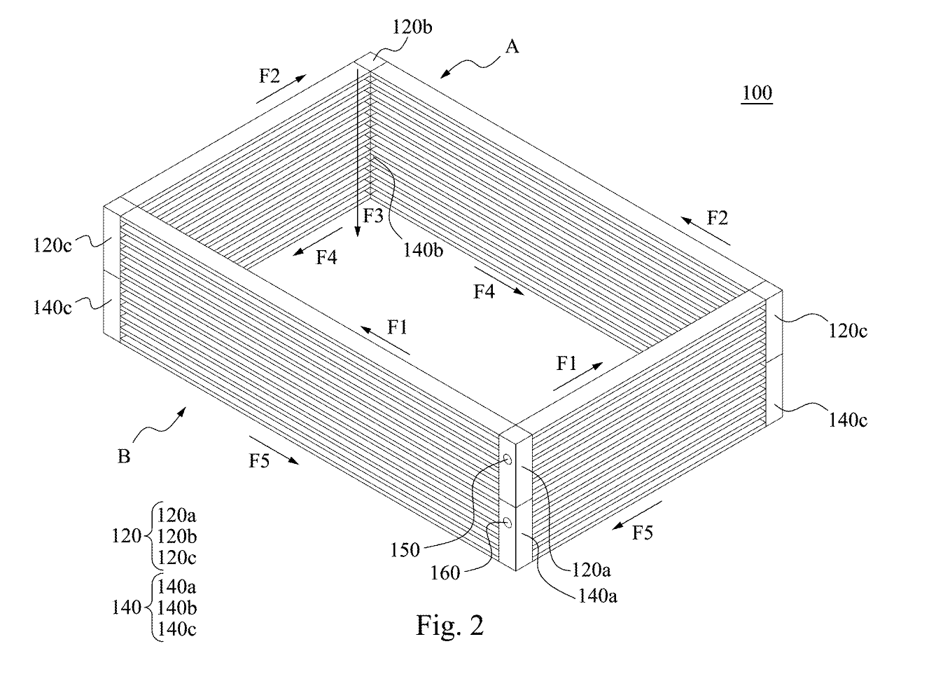

Reference is made to FIG. 2. FIG. 2 is a schematic view of a radiator 100 according to another embodiment of the present disclosure. In this embodiment, as shown in FIG. 2, the radiator 100 further includes a plurality of second pipe bodies 130 and a plurality of second connecting portions 140 (including the second connecting portions 140a, 140b, 140c). The second pipe bodies 130 are mutually connected to form a second annular structure B. The second pipe bodies 130 are configured to allow the cooling fluid C to flow through. The second connecting portions 140 are connected between the second pipe bodies 130. Each of the second connecting portions 140 is mutually communicated with the second pipe bodies 130 mutually connected. The first connecting portions 120 overlap on the second connecting portions 140. At least one of the second connecting portions 140 is mutually communicated with a corresponding one of the first connecting portions 120. Similarly, each of the first pipe bodies 130 includes a plurality of second subsidiary pipe bodies 131. The second subsidiary pipe bodies 131 are arranged mutually side by side.

In this embodiment, the inlet structure 150 is located at one of the first connecting portions 120. The outlet structure 160 is located at the corresponding one of the second connecting portions 140 overlapped by the corresponding one of the first connecting portions 120 at which the inlet structure 150 is located. To be more specific, as shown in FIG. 2, the inlet structure 150 is located at the first connecting portion 120a, and the outlet structure 160 is located at the second connecting portion 140a. The first connecting portion 120a overlaps on the second connecting portion 140a, and the first connecting portion 120b overlaps on the second connecting portion 140b. The first connecting portion 120b and the second connecting portion 140b are mutually communicated. In this way, after the cooling fluid C flows to the first connecting portion 120a through the inlet structure 150, the cooling fluid C then flows along the first subsidiary pipe bodies 111 along the flowing directions F1 at the two sides to the first connecting portions 120c, and then turns to flow along the flowing directions F2 to the first connecting portion 120b. Since the first connecting portion 120b and the second connecting portion 140b are mutually communicated, the cooling fluid C flowing to the first connecting portion 120b then flows to the second connecting portion 140b along the flowing direction F3. After the cooling fluid C flows to the second connecting portion 140b, the cooling fluid C then flows along the second subsidiary pipe bodies 131 along the flowing directions F4 at the two sides to the second connecting portions 140c, and then turns to flow along the flowing directions F5 to the second connecting portion 140a.

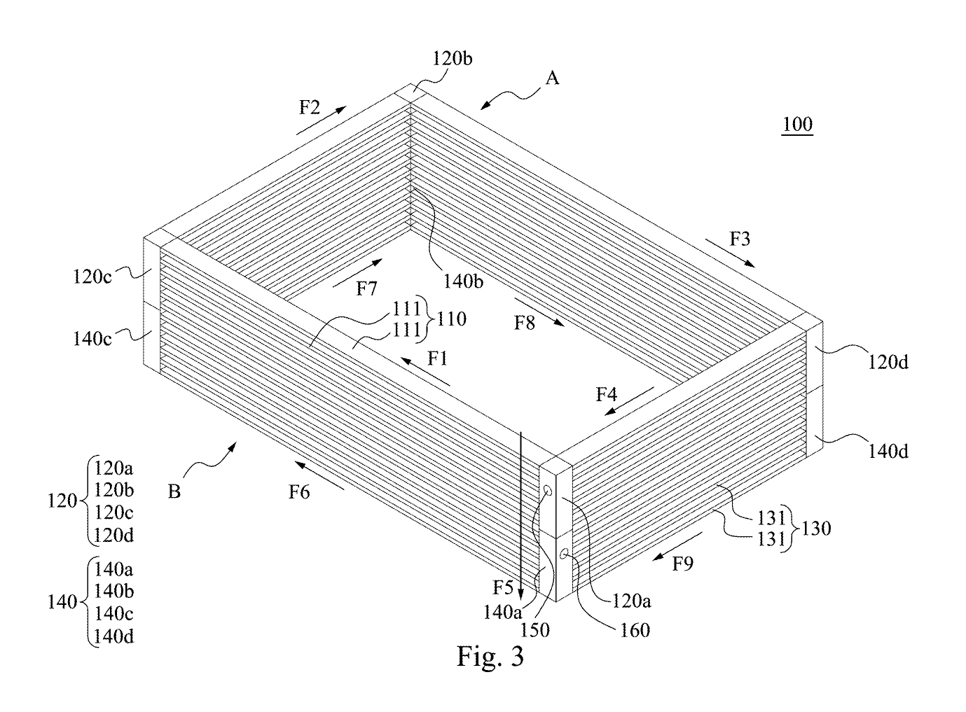

Reference is made to FIG. 3. FIG. 3 is a schematic view of a radiator 100 according to a further embodiment of the present disclosure. In this embodiment, as shown in FIG. 3, the inlet structure 150 is located at the first connecting portion 120a. The outlet structure 160 is located at the second connecting portion 140a. The first connecting portion 120a overlaps on the second connecting portion 140a. The first connecting portion 120a and the second connecting portion 140a are mutually communicated.

Reference is made to FIG. 4. FIG. 4 is a partial perspective view of the first connecting portion 120a and the second connecting portion 140a of FIG. 3. In this embodiment, as shown in FIG. 4, the first connecting portion 120a and the second connecting portion 140a mutually communicated respectively have a first isolating plate 121 and a second isolating plate 141 therein. The first isolating plate 121 isolates a first internal chamber S1 of the first connecting portion 120a into a first chamber S11 and a second chamber S12. The second isolating plate 141 isolates a second internal chamber S2 of the second connecting portion 140a into a third chamber S21 and a fourth chamber S22. The second chamber S12 and the third chamber S21 are mutually communicated. Moreover, the inlet structure 150 is communicated with the first chamber S11, and the outlet structure 160 is communicated with the fourth chamber S22.

Reference is made to FIGS. 3-4. In this way, after the cooling fluid C flows to the first chamber S11 of the first connecting portion 120a through the inlet structure 150, the cooling fluid C then flows along the first subsidiary pipe bodies 111 along the flowing direction F1 to the first connecting portion 120c, and then turns to flow along the flowing direction F2 to the first connecting portion 120b, and then turns to flow along the flowing direction F3 to the first connecting portion 120d, and then turns to flow along the flowing direction F4 to the second chamber S12 of the first connecting portion 120a. Since the second chamber S12 and the third chamber S21 are mutually communicated, the cooling fluid C flowing to the second chamber S12 then flows to the third chamber S21 of the second connecting portion 140a along the flowing direction F5. After the cooling fluid C flows to the third chamber S21, the cooling fluid C then flows along the second subsidiary pipe bodies 131 along the flowing direction F6 to the second connecting portion 140c, and then turns to flow along the flowing direction F7 to the second connecting portion 140b, and then turns to flow along the flowing direction F8 to the second connecting portion 140d, and then turns to flow along the flowing direction F9 to the fourth chamber S22 of the second connecting portion 140a.

In conclusion, when compared with the prior art, the aforementioned embodiments of the present disclosure have at least the following advantages.

(1) Since the first pipe bodies are mutually connected to form the first annular structure, the heated fluid in the cooling tank can be in contact with the first pipe bodies forming the first annular structure. In other words, the radiator can be disposed completely around an inner space inside the cooling tank to carry out heat exchange, such that the effect of the heat exchange between the heated fluid and the first pipe bodies can be strengthened.

(2) Since the width of each of the first pipe bodies is shorter than the height, the first pipe bodies forming the first annular structure can effectively increase the space utilization rate inside the cooling tank.

(3) Through the formation of the first annular structure, the degree of complexity of the pipelines of the radiator can be effectively reduced, further increasing the space utilization rate inside the cooling tank. Moreover, the radiator can be installed at the inner wall of the cooling tank in a simple and an easy manner, which is convenient to the users.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A radiator, comprising:
a plurality of first pipe bodies mutually connected to form a first annular structure, the first pipe bodies being configured to allow a cooling fluid to flow through, each of the first pipe bodies having a width and a height perpendicular to each other, the height being longer than the width.

2. The radiator of claim 1, wherein each of the first pipe bodies comprises a plurality of first subsidiary pipe bodies arranged mutually side by side.

3. The radiator of claim 1, wherein the first annular structure is a rectangular structure.

4. The radiator of claim 1, further comprising:
a plurality of first connecting portions connected between the first pipe bodies, each of the first connecting portions being mutually communicated with the first pipe bodies mutually connected.

5. The radiator of claim 4, further comprising:
a plurality of second pipe bodies mutually connected to form a second annular structure, the second pipe bodies being configured to allow the cooling fluid to flow through; and
a plurality of second connecting portions connected between the second pipe bodies, each of the second connecting portions being mutually communicated with the second pipe bodies mutually connected, the first connecting portions overlapping on the second connecting portions;
wherein at least one of the second connecting portions is mutually communicated with a corresponding one of the first connecting portions.

6. The radiator of claim 5, further comprising:
an inlet structure located at one of the first connecting portions; and
an outlet structure located at the corresponding one of the second connecting portions overlapped by the corresponding one of the first connecting portions at which the inlet structure is located.

7. The radiator of claim 5, wherein the corresponding one of the first connecting portions and the corresponding one of the second connecting portions mutually communicated respectively have a first isolating plate and a second isolating plate therein, the first isolating plate isolating a first internal chamber of the corresponding one of the first connecting portions into a first chamber and a second chamber, the second isolating plate isolating a second internal chamber of the corresponding one of the second connecting portions into a third chamber and a fourth chamber, the second chamber and the third chamber are mutually communicated.

8. The radiator of claim 4, further comprising:
an inlet structure located at one of the first connecting portions; and
an outlet structure located at one of the first connecting portions.

9. The radiator of claim 8, wherein the inlet structure and the outlet structure are located at different two of the first connecting portions.

10. The radiator of claim 8, wherein the inlet structure and the outlet structure are both located at one of the first connecting portions.
